(19) United States
(12) Patent Application Publication
(10) Pub. No.: US 2025/0357339 A1
(43) Pub. Date: Nov. 20, 2025

(54) PROCESS OF MANUFACTURING AN ELECTRONIC DEVICE INCLUDING A MEMORY CIRCUIT

(71) Applicant: STMicroelectronics International N.V., Geneva (CH)

(72) Inventors: Olivier WEBER, Grenoble (FR); Franck ARNAUD, St Nazaire Les Eymes (FR)

(73) Assignee: STMicroelectronics International N.V., Geneva (CH)

(21) Appl. No.: 19/199,125

(22) Filed: May 5, 2025

(30) Foreign Application Priority Data
May 14, 2024 (FR) FR2404887

(51) Int. Cl. H01L 23/528; H10B 63/00; H10B 63/10; H10N 70/00

(52) U.S. Cl. CPC H01L 23/5283; H01L 23/528; H10B 63/10; H10B 63/32; H10B 63/34; H10N 70/068

(57) ABSTRACT

An electronic device includes a semiconductor substrate, an insulating layer on and in contact with the semiconductor substrate, and a memory circuit including a plurality of memory cells. Each memory cell includes a bipolar selection transistor disposed in and on the semiconductor substrate, each bipolar selection transistor including a base region, an emitter region, and a collector region. Each bipolar selection transistor includes an insulation structure made of a first dielectric material, the insulation structure including an upper part extending vertically through the insulating layer, and a lower part extending vertically through the semiconductor substrate between the base region and the emitter region. The side faces of the upper part of the insulation structure are covered by spacers made of a second dielectric material.

### CROSS-REFERENCE TO RELATED APPLICATION(S)

This application claims the priority benefit of French patent application number FR2404887, filed on May 14, 2024, entitled “Procédé de fabrication d'un dispositif électronique comprenant un circuit mémoire” which is hereby incorporated by reference to the maximum extent allowable by law.

### BACKGROUND

### Technical Field

The present description relates generally to electronic devices and more particularly to electronic devices including a memory circuit.

### Description of the Related Art

Electronic devices include both memory circuits and logic circuits. Of particular interest here are electronic devices including memory circuits including memory elements arranged in an array, each memory element being associated with a bipolar selection transistor. This transistor is used to program, erase, or read each memory element separately.

It would be desirable to improve at least some aspects of known electronic devices.

### BRIEF SUMMARY

One embodiment provides an electronic device including:
a semiconductor substrate;
an insulating layer covering the semiconductor substrate, on and in contact with the semiconductor substrate; and
a memory circuit including a plurality of memory cells, each including a bipolar selection transistor disposed in and on the semiconductor substrate, each bipolar selection transistor including a base region, an emitter region, and a collector region,
wherein each selection bipolar transistor includes an insulation structure made of a first dielectric material, the insulation structure including an upper part extending vertically through the insulating layer, and a lower part extending vertically through the semiconductor substrate between the base region and the emitter region, the side faces of the upper part of the insulation structure being covered by spacers made of a second dielectric material.

According to one embodiment, the device further includes a logic circuit including a plurality of fin field-effect transistors arranged in and on the semiconductor substrate, each fin field-effect transistor including a source region and a drain region,
wherein two adjacent fin field-effect transistors are separated by a further insulation structure made of the first dielectric material, the insulation structure including an upper part extending vertically through the insulating layer, and a lower part extending vertically through the semiconductor substrate between the drain region and the source region of the two adjacent transistors, the side faces of the upper part of the insulation structure being covered by spacers made of the second dielectric material.

According to one embodiment, the insulation structures of the memory circuit and the insulation structures of the logic circuit have the same depth.

According to one embodiment, the insulation structures of the memory circuit and the insulation structures of the logic circuit have different depths.

According to one embodiment, each memory cell includes a memory element including a layer made of phase-change material.

According to one embodiment, the memory circuit includes an interconnection stack arranged on the semiconductor substrate, including a succession of levels within which interconnection elements are defined.

According to one embodiment, the memory elements are arranged on top of the interconnection stack.

Another embodiment provides a process of manufacturing, in and on a semiconductor substrate, an electronic device including a memory circuit including a plurality of memory cells each including a selection bipolar transistor formed in and on the semiconductor substrate, each selection bipolar transistor including a base region, an emitter region, and a collector region, the process including the steps of:
forming sacrificial gates made of sacrificial material on the semiconductor substrate;
forming spacers made of dielectric material on the side faces of the sacrificial gates;
removing the sacrificial material in the sacrificial gates, and etching the substrate opposite the sacrificial gates so as to form openings surrounded in an upper part by the spacers and extending through a lower part within the substrate, and filling the openings with a other dielectric material such a way to form insulation structures made of the other dielectric material; and
forming an insulating layer on and in contact with the semiconductor substrate, the insulation structures thus including an upper part extending vertically through the insulating layer and a lower part extending vertically through the semiconductor substrate between the base region and the emitter region of the bipolar transistors, the side faces of the upper part of each insulation structure being covered by the spacers.

According to one embodiment, the device further includes a logic circuit, the logic circuit including a plurality of fin field-effect transistors each including a source region and a drain region, the process including the steps of:
forming sacrificial gates made of sacrificial material on the semiconductor substrate;
forming spacers made of dielectric material on the side faces of the sacrificial gates;
removing the sacrificial material in the sacrificial gates, and etching the substrate opposite the sacrificial gates so as to form openings surrounded in an upper part by the spacers and extending in a lower part through the substrate, and filling the openings with the other dielectric material so as to form further insulation structures of the other dielectric material; and
forming the insulating layer on and in contact with the semiconductor substrate, the further insulation structures thus including an upper part extending vertically through the insulating layer and a lower part extending vertically through the semiconductor substrate between the source region and the drain region of each fin field-effect transistor, the side faces of the upper part of the further insulation structure being covered by the spacers.

According to one embodiment, the steps for forming the insulation structures of the memory circuit and the further insulation structures of the logic circuit are common.

In one embodiment, a process includes forming first sacrificial gates of a first sacrificial material on a semiconductor substrate, forming first spacers of a first dielectric material on side faces of the first sacrificial gates, and forming, in and on the semiconductor substrate, a plurality of bipolar transistors each including a base region, an emitter region, and a collector region. The process includes forming first openings surrounded in an upper part by the first spacers and extending in a lower part through the substrate by removing the first sacrificial gates and etching the substrate and forming first insulation structures by filling the openings with a second dielectric material. The process includes forming an insulating layer on and in contact with the semiconductor substrate. The first insulation structures includes an upper part extending vertically through the insulating layer and a lower part extending vertically through the semiconductor substrate between the base region and the emitter region of the bipolar transistors. Side faces of the upper part of each first insulation structure are covered by the first spacers.

In one embodiment, each bipolar transistor is part of a respective memory cell of a memory circuit.

In one embodiment, the process includes forming second sacrificial gates on the semiconductor substrate, forming second spacers of the first dielectric material on side faces of the second sacrificial gates, and forming a plurality of fin field-effect transistors each including a source region and a drain region. The process includes forming second openings surrounded in an upper part by the spacers and extending in a lower part through the substrate by removing the second sacrificial gates from between the second spacers and etching the substrate. The process includes forming second insulation structures by filling the second openings with the second dielectric material. The second insulation structures include an upper part extending vertically through the insulating layer and a lower part extending vertically through the semiconductor substrate between the source region and the drain region of each fin field-effect transistor. Side faces of the upper part of the second insulation structure are covered by the second spacers.

In one embodiment, the fin field-effect transistors are part of a logic circuit.

In one embodiment, the process includes forming the first insulation structures and the second insulation structures simultaneously.

In one embodiment, a method includes forming a first sacrificial gate structure on a semiconductor substrate and forming first spacers of a first dielectric material on sidewalls of the first sacrificial gate structure. The method includes forming a base region and an emitter region of a bipolar transistor in the semiconductor substrate each in contact with a respective one of the first spacers and replacing the first sacrificial gate structure with a first insulation structure of a second dielectric material extending into the semiconductor substate.

In one embodiment, the method includes forming an insulating layer in contact with the semiconductor substrate, wherein the first insulation structure extends vertically through the insulating layer.

In one embodiment, the method includes forming the base region and the emitter region in separate epitaxial growth processes from the semiconductor substrate.

In one embodiment, the method includes forming a second sacrificial gate structure on the semiconductor substrate, forming second spacers of the first dielectric material on sidewalls of the second sacrificial gate structure, and forming a first source/drain region of a first fin field-effect transistor and a second source/drain region of a second fin field-effect transistor each in contact with a respective one of the second spacers. The method includes replacing the second sacrificial gate structure with a second insulation structure of the second dielectric material extending into the semiconductor substate.

In one embodiment, the method includes forming the first source/drain region, the second source/drain region, and the base region in a same first epitaxial growth process.

In one embodiment, the method includes forming the emitter region in a second epitaxial growth process.

In one embodiment, the first and second fin field-effect transistors are part of a logic circuit.

In one embodiment, the bipolar transistor is part of a memory cell of a memory circuit.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1A, FIG. 1B, and FIG. 1C are schematic partial views of an example electronic device according to a first embodiment;

FIG. 2, FIG. 3, FIG. 4, FIG. 5, FIG. 6, FIG. 7A, FIG. 7B, FIG. 7C, FIG. 7D, FIG. 8A, FIG. 8B, FIG. 9A, FIG. 9B, FIG. 10A, FIG. 10B, FIG. 11A, FIG. 11B, FIG. 12A, FIG. 12B, FIG. 13A, FIG. 13B, FIG. 14A, FIG. 14B, FIG. 15A, FIG. 15B, FIG. 16A, and FIG. 16B are views illustrating steps in an example process of manufacturing the electronic chip illustrated in FIGS. 1A, 1B, and 1C;

FIG. 17A and FIG. 17B are schematic partial views of an example electronic device according to a second embodiment; and

FIG. 18A and FIG. 18B are schematic partial views of an example electronic device according to a third embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10% or 10°, and preferably within 5% or 5°.

As used herein, the source and drain terminals of transistors may be referred to as source/drain terminals where it is not specified if a particular terminal is a source terminal or a drain terminal.

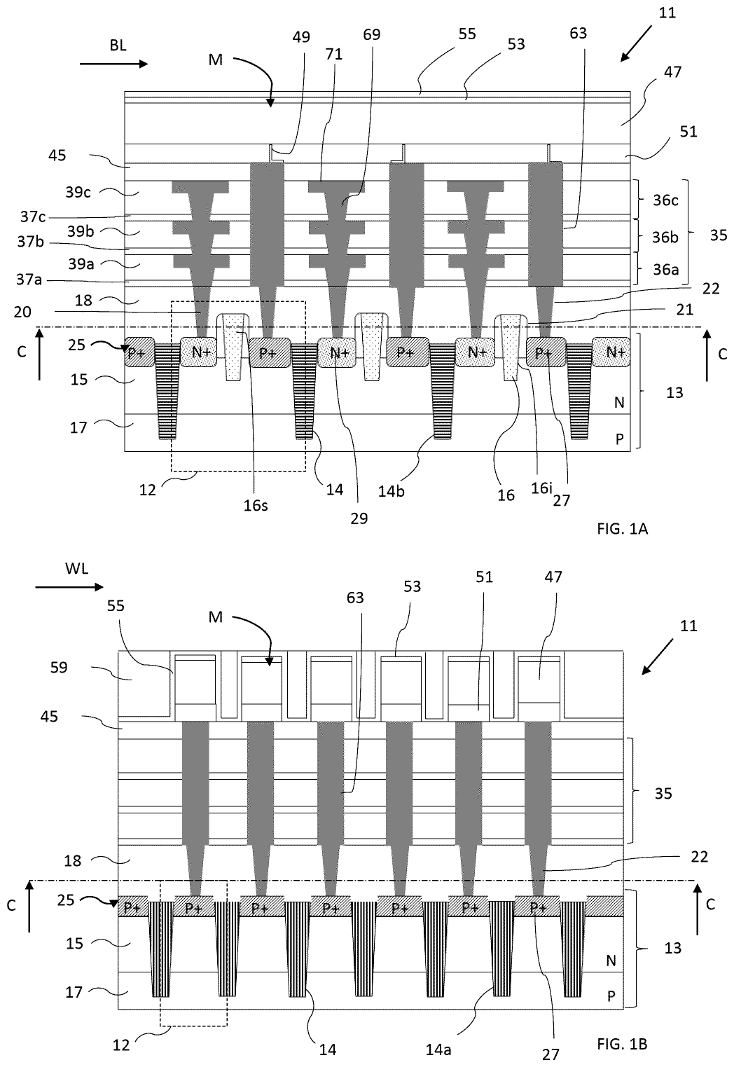

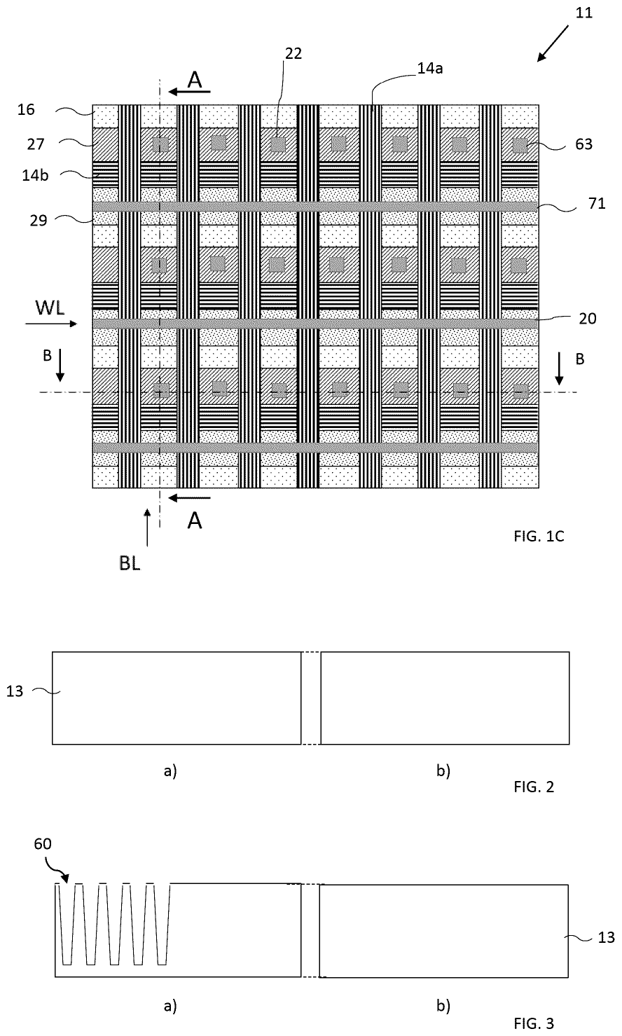

FIG. 1A, FIG. 1B, and FIG. 1C are schematic partial sectional views of an example electronic device according to a first embodiment. More specifically, FIGS. 1A and 1B are vertical sectional views of said device, and FIG. 1C is a horizontal sectional view of said device, FIG. 1A corresponding to a view along cutting plane AA shown in FIG. 1C, FIG. 1B corresponding to a view along cutting plane BB shown in FIG. 1C, and FIG. 1C corresponding to a top view along horizontal cutting plane CC shown in FIGS. 1A and 1B. Note that in FIG. 1C, some of the elements have been illustrated in transparency.

In particular, FIG. 1A, FIG. 1B, and FIG. 1C illustrate a memory circuit of electronic device 11. By way of example, the electronic device 11 includes, in a portion not shown, a logic circuit. The logic and memory circuits are, for example, fabricated concurrently in and on the same semiconductor substrate.

Device 11 is a microchip, for example.

Device 11 includes a semiconductor substrate 13. By way of example, substrate 13 is made of silicon or a silicon-based material.

The substrate 13 includes, for example, a semiconductor layer 15 doped with a first conductivity type, for example of the N-type, for example doped with arsenic or phosphorus atoms. For example, layer 15 rests on, and is in contact with, another semiconductor layer 17 of substrate 13 doped with a second conductivity type, opposite to the first conductivity type, for example of the P-type, for example doped with boron atoms.

The substrate 13 includes, for example, a semiconductor layer 25. For example, layer 25 rests on, and is in contact with, layer 15. Thus, layer 25 is separated from layer 17 by layer 15. For example, layer 25 is flush with an upper face of substrate 13. Semiconductor layer 25 is, for example, a layer epitaxially formed from the upper face of layer 15. For example, layer 25 is made of silicon, such as single-crystal silicon. Layer 25 includes, for example, a plurality of regions 27 and regions 29. In the embodiment shown in FIGS. 1A to 1C, the regions 27 extend longitudinally as lines in a first direction, and the regions 29 extend longitudinally as lines in the same first direction. By way of example, regions 27 and 29 extend in the direction of the plane shown in FIG. 1B. The substrate 13 thus includes, in the example of FIGS. 1A-C, lines including alternating regions 27 and 29 extending in the first direction.

Each region 27 or 29 preferably extends over the entire height of layer 25. Each region 27 or 29 is thus flush with the upper face of layer 25. Each region 27 or 29 is in contact, for example, with the lower face of layer 15.

For example, regions 27 are doped with a second conductivity type, for example of the P-type. By way of example, regions 27 include germanium and boron atoms. Regions 27 are, for example, more heavily doped than layer 17.

For example, regions 29 are doped with the first type of conductivity, for example of the N-type. By way of example, regions 29 include phosphorus atoms. Regions 29 are, for example, more heavily doped than layer 15.

The device 11 includes a plurality of transistors 12 formed in and on the substrate 13. Each transistor 12 includes, for example, a single region 27 and a single region 29 of the substrate 13.

For example, the transistors 12 are separated from one another, and are for example electrically insulated, by insulating trenches 14, or insulation trenches 14. The insulating trenches 14 are, for example, Shallow Trench Insulation (STI) trenches. Trenches 14 are, for example, divided into two categories: trenches 14a extending longitudinally in the first direction, and trenches 14b extending longitudinally in the second direction. By way of example, the insulation trenches 14a and 14b form a grid when viewed from above.

The insulation trenches 14 extend, for example, from a face located at an intermediate level between the upper and lower faces of layer 25. The trenches 14 preferably extend through part of layer 25, through layer 15, and through part of layer 17. The insulation trenches 14 are for example filled with a dielectric material, such as silicon oxide. Trenches 14a and 14b have, for example, the same depth. The depth of trenches 14 is, for example, between 250 nm and 400 nm.

The transistors 12 are thus arranged in an array within the grid formed by the trenches 14. The substrate 13 thus includes rows and columns of transistors 12.

Each transistor 12 is included within an elementary memory cell. Each memory cell further includes a memory element M, preferably formed at least partially in line with said transistor 12, for example in line with region 27 of said transistor 12. Regions 29, unlike regions 27, are for example not topped by memory elements M. By way of example, within each memory cell, transistor 12 is a selection transistor of memory element M.

When viewed from above, the memory elements M, for example, are organized in an array of rows and columns. These are referred to respectively as word lines extending in the second direction, i.e., the direction of the trenches 14b, and bit lines extending in the first direction, i.e., the direction of the trenches 14a. By way of example, each memory element M is located at the crossing of a bit line and a word line. By way of example, the memory elements M illustrated in FIG. 1B are memory elements M on the same word line WL, while the memory elements illustrated in FIG. 1A are memory elements on the same bit line BL. In FIG. 1B, only six bit lines are illustrated, and in FIG. 1A, only three word lines are illustrated. However, in practice, a memory circuit could include a different number of bit lines and word lines, for example greater than six and three respectively.

By way of example, each insulation trench 14b extends longitudinally in the direction of the word lines, over the entire length of the word lines. By way of example, each insulation trench 14a extends longitudinally in the direction of the bit lines, over the entire length of the bit lines. The array of transistors 12 corresponds substantially to the array of memory elements M.

In the example shown in FIGS. 1A-1C, each transistor 12 is defined by layer 17, regions 27, and regions 29 coupled to layer 15. In this example, region 27 forms an emitter region of transistor 12, layer 15 forms a base region of transistor 12, region 29 forms a base access region of transistor 12, and layer 17 forms a collector region of transistor 12. By way of example, the collector is common to all transistors 12 in the array and is, for example, connected to ground. In this example, base region 15 is common to all transistors 12 on the same word line of the memory circuit.

The transistors 12 are, for example, bipolar selection (BJT, Bipolar Junction Transistor) transistors of PNP-type.

Device 11 includes an insulating layer 18 covering the upper face of semiconductor substrate 13, and more specifically the upper face of layer 25. The insulating layer 18 is, for example, in contact with the upper face of layer 25. For example, insulating layer 18 covers the entire upper face of layer 25. The insulating layer 18 has a thickness of between 80 nm and 300 nm, for example between 120 nm and 200 nm.

Device 11 further includes insulation structures or trenches 16. The trenches 16 are, for example, Single Diffusion Break (SDB) trenches. For example, trenches 16 extend through layer 25 separating thus region 27 from region 29 of each transistor 12. In other words, regions 27 and 29 of each transistor 12 are separated by a trench 16. By way of example, each trench 16 extends longitudinally in the direction of the word lines, for example along the entire length of the word lines.

Each trench 16, for example, is located between two trenches 14b. Thus, in the bit line direction, the substrate 13 includes alternating trenches 14b and trenches 16.

Each insulation trench 16 includes an upper part 16s extending vertically through the insulating layer 18, and a lower part 16i extending vertically through the semiconductor substrate 13.

The side faces of the upper part 16s of each insulation trench 16 are covered by spacers 21 made of a second dielectric material. The spacers 21 are, for example, made of an electrically insulating material, such as silicon nitride. By way of example, the upper part 16s of each trench 16 includes a lower portion for which the flanks of the surrounding spacer 21 are in contact with layer 25 and more precisely with regions 27 and 29. By way of example, the lower face of each spacer 21 rests on the upper face of layer 15, for example between regions 27 and 29.

The lower part 16i of the trenches 16 extends through layer 15 from the upper face of layer 15. By way of example, the lower part 16i of the trenches 16 does not extend as far as layer 17.

The side faces of the lower part 16i of each insulation trench 16 are not covered by spacers, and the insulation trench 16 is, in this part, directly in contact with the layer 15 of the substrate 13.

By way of example, trenches 16 extend less deeply than trenches 14. The trenches 16 extend, for example, from a face located at an intermediate level between the upper and lower faces of the layer 18. The insulation trenches 16 are for example filled with a dielectric material, such as silicon oxide. The trenches 16 have, for example, a height or depth (measured between the upper and lower faces of the trenches 16) of between 50 nm and 150 nm.

For example, vias 20 and 22 pass through layer 18. The vias 20 and 22 are, for example, in contact, by their lower faces, with the upper face of layer 25 so that each region 27 and 29 is topped by a via 20 or 22. By way of example, vias 20 are in contact with regions 27. By way of example, vias 22 are in contact with regions 29. Vias 20 and 22 extend, for example, over the entire height of layer 18. Vias 20 and 22 thus extend from the upper face of layer 18 to the lower face of layer 18.

For example, layer 18 is topped by an interconnection stack 35. In this example, interconnection stack 35 is formed between substrate 13 and memory elements M. Interconnection stack 35 is formed, for example, on the upper face of insulating layer 18, and covers for example the entire surface of insulating layer 18.

Interconnection stack 35 is for example formed of a succession of levels 36, each level 36 including an insulating layer 37 and an insulating layer 39. Interconnection stack 35 includes, for example, a level 36a, including an insulating layer 39a formed on and in contact with the upper face of insulating layer 18. In level 36a, interconnection stack 35 further includes an insulating layer 37a formed on insulating layer 39a. The insulating layer 37a is, for example, formed over the entire surface of the insulating layer 39a. By way of example, the insulating layer 37a is in contact, by its lower face, with the upper face of the insulating layer 39a.

Interconnection stack 35 could further include additional levels formed on level 36a, i.e., on and in contact with insulating layer 37a. In FIGS. 1A and 1B, interconnection stack 35 includes two additional levels 36b and 36c, for example formed by layers 37b and 39b, and by layers 37c and 39c, respectively. In practice, the number of levels in interconnection stack 35 could be different from three, for example greater than three.

By way of example, the interconnection stack 35 has a thickness of between 200 nm and 800 nm, for example between 250 nm and 600 nm, for example of the order of 350 nm.

By way of example, insulating layers 18 and 37 are made of a material with a low dielectric constant, for example a material with a dielectric constant (corresponding to the permittivity of said material relative to the permittivity of vacuum) of less than 5, for example less than 4. The insulating layers 37 are made of SiCN, for example. By way of example, insulating layers 39 are made of low permittivity oxides, known as “low k” or “ultra low k”.

Each level 36 includes conductive vias 69 and conductive tracks 71, the tracks 71 extending within layer 39 from, for example, the upper face of layer 39, thus being flush with the upper face of layer 39. Preferably, the tracks 71 of a level 36 extend exclusively within the layer 39 of said level 36. The vias 69 of a level of stack 35 extend through layer 39 and through layer 37 of the same level 36. More precisely, the vias 69 of a level of stack 35 extend from the lower face of a track 71 of the same level to the lower face of layer 37 or to the upper face of a via 20 or 22 passing through layer 18.

For example, the vias and conductive tracks 71 and 69 are made of a metal material, such as copper. By way of example, the conductive tracks 71 extend laterally over a surface area of between 20 nm by 20 nm and 60 nm by 60 nm, for example of the order of 30 nm by 30 nm. By way of example, the conductive tracks 71 extend laterally over a surface area greater than or equal to the area of the vias 69.

In the embodiment shown in FIGS. 1A to 1C, the memory elements M are formed on the upper face of the stack 35. By way of example, the memory elements M are separated from the stack 35 by an insulating layer 45. The insulating layer 45 is made, for example, of silicon nitride, SiCN, an oxide or a stack of several of these materials, for example a stack of SiCN and an oxide. For example, layer 45 is in contact, via its lower face, with the upper face of layer 39c. The layer 45 is further in contact, via its upper face, with the lower face of the memory elements M.

By way of example, the memory elements M are phase-change memory elements. By way of example, each element includes a layer 47 of a phase-change material, such as a chalcogenide material, for example a germanium, antimony, and tellurium alloy (GeSbTe) referred to as GST. For example, layer 47 has a thickness of between 30 nm and 100 nm, for example of the order of 50 nm. Memory elements M on the same bit line, for example, include a common layer 47. So, for example, device 11 includes as many layers 47 as there are bit lines. Each layer 47 extends in the direction of the bit lines.

In each memory element M, the phase-change material is, for example, controlled by a metallic resistive heating element 49 located beneath the phase-change material. The element 49 is, for example, in contact with the lower face of the layer 47 via its upper face. For example, the element 49 is laterally surrounded by a layer of thermal insulation 51. For example, each element 49 is “L”-shaped as viewed in the cutting plane of FIG. 1A. By way of example, layer 51 is made of nitride. By way of example, heating element 49 has, for example, a height of between 30 nm and 100 nm, for example of the order of 60 nm.

The layer 47 is, for example, topped by a layer 53, for example made of a conductive material, such as a metal material. More precisely, the upper face of each layer 47 is, for example, at least partially covered, for example entirely covered, by a layer 53. Each layer 53 preferably extends, in the direction of the bit lines, over the entire length of the layer 47.

By way of example, in each memory element M, the metal element 49 and the layer 53 respectively form a bottom and a top electrode of the memory element M, and more precisely electrodes of the variable-resistance resistive element formed by the layer 47 made of the phase-change material. By way of example, the memory elements M of the same bit line are topped by the same layer 53. In other words, the top electrodes 53 of the memory elements M on the same bit line are interconnected.

Each memory element M, for example, is covered by an insulating layer 55 protecting, for example, the layer 47 made of the phase-change material from oxidation. By way of example, layer 55 covers the upper face of layer 53 and the sides of layers 53, 47, and 51. For example, layer 55 is made of a dielectric material. For example, insulating layer 55 is made of a nitride, such as silicon nitride.

Memory elements M on adjacent bit lines, for example, are insulated from one another by an insulating layer 59. Insulating layer 59 is made, for example, of a material with a low dielectric constant. Alternatively, layer 59 is made of an oxide, such as silicon dioxide.

Thus, in the embodiment shown in FIGS. 1A to 1C, each memory element M is electrically connected to the selection transistor 12 with which it is associated via a conductive via 63 passing through all levels of the interconnection stack 35. By way of example, via 63 passes through all insulating layers 37 and 39 of interconnection stack 35 located between layer 45 and layer 18.

By way of example, the via 63 associated with each memory element M is in contact, via its upper face, with the lower face of the resistive heating element 49 of the memory element M. The via 63 is, for example, in contact, via its lower face, with a conductive via 22, itself in contact with the upper face of the region 27 of the transistor 12 associated with the memory element M. In other words, for each memory element M, the corresponding via 63 electrically couples the heating element 49 of the memory cell to the underlying region 27.

For example, conductive via 63 is made of a metal material. For example, conductive via 63 is made of tungsten. Alternatively, the conductive via is made of cobalt or copper. The conductive via 63 has, for example, a width, taken in the plane of FIGS. 1A and 1n the plane of FIG. 1B, of between 20 nm and 100 nm, for example of the order of 40 nm.

By way of example, vias 69 extend under layer 47 to the outside of the memory circuit, where they can be connected to apply potentials to the word lines of memory elements M.

By way of example, layer 53 is connected, via its upper face, to a conductive element, so that potentials can be applied to the bit lines of memory elements M.

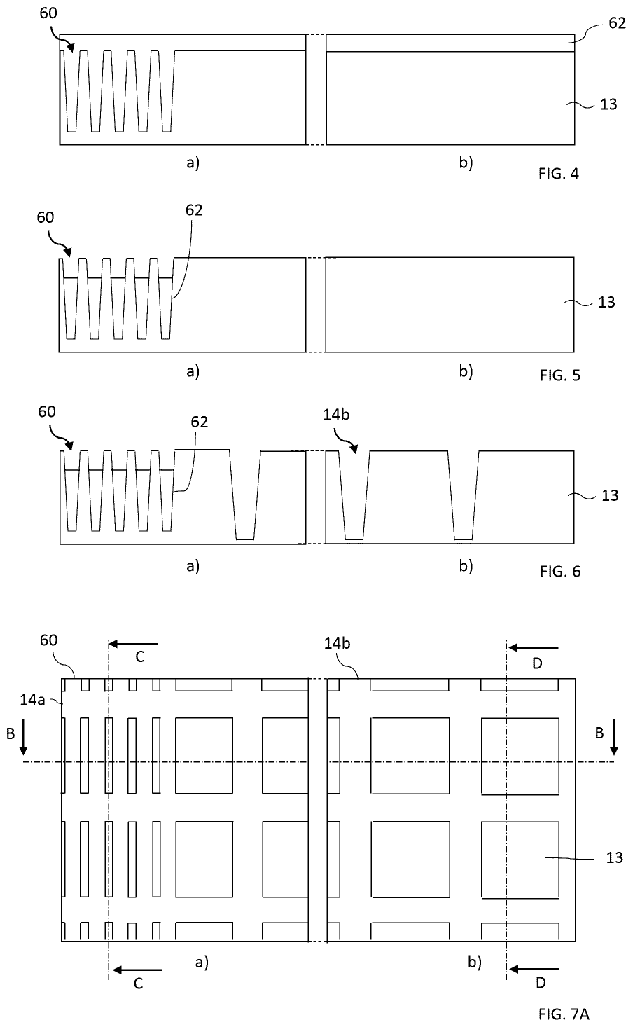

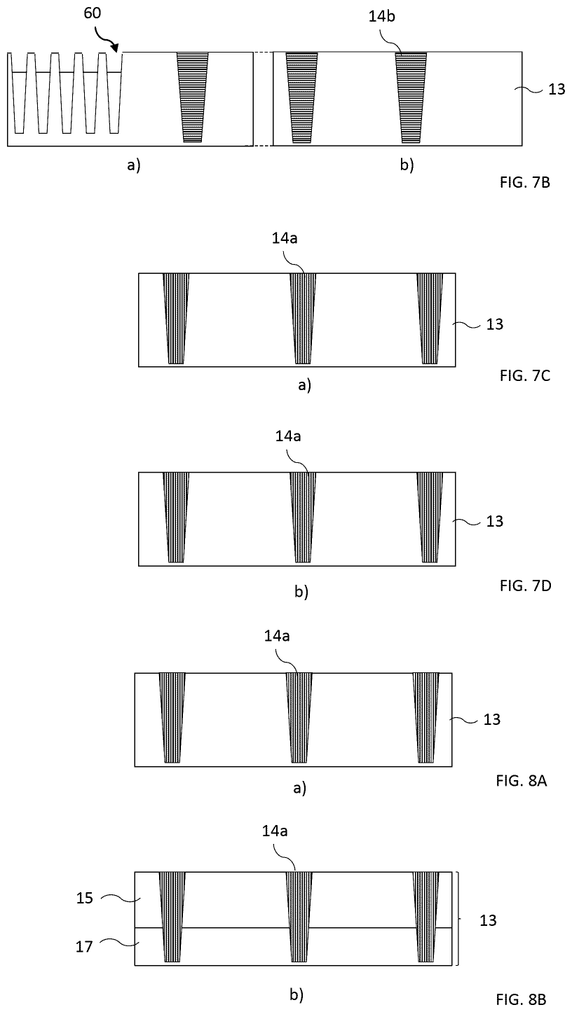

FIG. 2, FIG. 3, FIG. 4, FIG. 5, FIG. 6, FIG. 7A, FIG. 7B, FIG. 7C, FIG. 7D, FIG. 8A, FIG. 8B, FIG. 9A, FIG. 9B, FIG. 10A, FIG. 9B, FIG. 10A, FIG. 10B, FIG. 11A, FIG. 11B, FIG. 12A, FIG. 12B, FIG. 13A, FIG. 13B, FIG. 14A, FIG. 14B, FIG. 15A, FIG. 15B, FIG. 16A, and FIG. 16B are views illustrating steps in an example process for manufacturing the electronic device shown in FIGS. 1A, 1B, and 1C.

More specifically, FIGS. 2 to 16B are views illustrating a process for concurrently manufacturing, or co-integrating in the same integrated circuit device, the memory circuit of chip 11 illustrated in FIGS. 1A to 1C, including bipolar selection transistors, and a logic circuit, for example adjacent to the memory circuit, including Fin Field-Effect Transistors (FinFETs). FIGS. 2 to 16B show two regions a) and b) of the device, in which two bipolar selection transistors and two FinFET transistors are respectively formed. It is understood that, in practice, region a) may include a number of selection bipolar transistors greater than two, and region b) may include a number of FinFET transistors greater than two.

FIG. 2 illustrates a schematic partial sectional view of a starting structure including the semiconductor substrate 13. In FIG. 2, the substrate 13 includes the first region a) in and on which a FinFET transistor is formed in the process described hereinafter, and the second region b) in and on which a selection bipolar transistor is formed in the process described hereinafter.

FIG. 3 illustrates a schematic partial sectional view of a structure obtained at the end of a step for forming trenches 60 in the first region a) of the substrate 13 shown in FIG. 2.

Forming trenches 60 allows the fins of FinFET transistors to be defined between trenches 60. By way of example, trenches 60 extend in the direction of the bit lines, i.e., in the direction orthogonal to the direction of the cutting plane shown in FIG. 3.

The trenches 60 extend through the substrate 13, for example, from the upper face of the substrate 13.

By way of example, in sectional view, the trenches 60 are not shaped as a rectangle, the bottom of which is orthogonal to the side faces. For example, in sectional view, the trenches 60 are trapezoidal shaped in which the width of the trenches 60 at the upper face of the trenches 60 is greater than the width of the trenches 60 at the lower face of the trenches 60. By way of example, the trenches have a pitch of between 20 nm and 100 nm, for example between 30 nm and 50 nm. By way of example, the trenches 60 have a width, taken at the upper face of the substrate 13, of between 10 nm and 90 nm, for example of between 20 nm and 40 nm. By way of example, trenches 60 extend to a depth of between 20 nm and 400 nm, for example between 100 nm and 200 nm, for example of the order of 150 nm. The trenches 60 define the fins of the transistors which have, for example, a width of between 2 nm and 30 nm, for example between 5 nm and 15 nm, for example between 7 nm and 8 nm.

FIG. 4 illustrates a schematic partial sectional view of a structure obtained at the end of a step of depositing a layer 62 on the upper face of the structure illustrated in FIG. 3.

More specifically, in this step, layer 62 is deposited on the upper face of substrate 13 and in trenches 60. By way of example, in this step, the layer 62 completely covers the upper face of the substrate 13. For example, layer 62 is made of a dielectric material, such as an oxide.

FIG. 5 illustrates a schematic partial sectional view of a structure obtained at the end of a step of removing layer 62 from an upper part of the structure illustrated in FIG. 4.

More specifically, in a first stage, layer 62 is removed from the upper face of substrate 13 so as to expose the upper face of substrate 13. This removal is performed, for example, by Chemical Mechanical Polishing (CMP). Removal of layer 62 is stopped, for example, when the upper face of substrate 13 is exposed.

In a second stage, in this step, the layer 62 is removed from an upper part of the trenches 60, so that the layer 62 remains only in a lower part of the trenches 60. This removal is performed, for example, to a depth of between 10 nm and 100 nm, for example of the order of 50 nm.

FIG. 6 illustrates a schematic partial sectional view of a structure obtained at the end of a step for forming trenches 14b in the substrate 13 shown in FIG. 5.

The trenches 14b are, for example, formed in the substrate 13 by extending through the substrate 13 from the upper face of the substrate 13. By way of example, the trenches 14b extend to a depth greater than the depth of the trenches 60. For example, the trenches 14b are formed in the substrate 13 in the first a) and second b) regions of the substrate 13. By way of example, trenches 14b allow, as regards some of which being located in the memory circuit, insulating adjacent bit lines from each other, and as regards some of which being located between the logic circuit and the memory circuit, insulating the logic circuit from the memory circuit.

FIGS. 7A, 7B, 7C, and 7D illustrate schematic partial views of a structure obtained at the end of a step for forming trenches 14a in the substrate 13 shown in FIG. 6. More particularly, FIGS. 7B, 7C, and 7D are sectional views, and FIG. 7A is a top view of the structure obtained at the end the step for forming trenches 14a in the substrate 13 shown in FIG. 6, FIG. 7B being a sectional view according to cutting plane BB shown in FIG. 7A, FIG. 7C being a sectional view according to cutting plane CC shown in FIG. 7A, and FIG. 7D being a sectional view according to cutting plane DD shown in FIG. 7A. FIG. 7C further corresponds to a sectional view within the first region a) of substrate 13, and FIG. 7D corresponds to a sectional view within the second region b) of substrate 13.

The trenches 14a are, for example, formed through the substrate 13 by extending through the substrate 13 from the upper face of the substrate 13. By way of example, the trenches 14a extend to a depth greater than the depth of the trenches 60. For example, the trenches 14a are formed in the substrate 13 in the first a) and second b) regions of the substrate 13. By way of example, trenches 14a allow adjacent word lines to be insulated. By way of example, the same trench 14a may extend both through the first region a) of substrate 13 and through the second region b) of substrate 13. Alternatively, the same trench 14a may extend only through the first region a) of substrate 13 or only through the second region b) of substrate 13. Alternatively, the same trench 14a may extend only over a portion of the first region a) of substrate 13 and/or only over a portion of the second region b) of substrate 13.

By way of example, the formation of trenches 14 includes a prior step of depositing a protective layer, for example made of nitride, allowing the structure to be protected in areas where no trenches 14 are to be formed. By way of example, at the end of forming the trenches 14a and 14b, they are, for example, filled with a semiconductor material. By way of example, trenches 14a and 14b are filled with an oxide. The step of filling trenches 14a and 14b is followed, for example, by a CMP step stopping on the upper face of the aforementioned protective layer. By way of example, in one embodiment, after the CMP step, the protective layer is removed so as to expose the upper face of substrate 13.

Although it has been described in the present embodiment that trenches 14a and 14b are filled with the dielectric material in a single step, one may provide that filling the trenches 14b is performed at the end of the step illustrated in FIG. 6, before forming trenches 14a.

In addition, although it has been described in the present embodiment that trenches 14b are performed before trenches 14a, one may provide that the order in which these trenches are performed is reversed and that trenches 14a are performed before trenches 14b.

By way of example, although not shown, at the end of forming the trenches 14a and 14b, the structure is covered by a layer made of a dielectric material, for example an oxide. The oxide layer thus covers the upper face of substrate 13 in the first a) and second b) regions, the upper face of trenches 14a and 14b, the upper face of layer 62 in trenches 60 and the sides of trenches 60 above layer 62.

FIGS. 8A and 8B illustrate schematic partial sectional views of a structure obtained at the end of a step of forming layers 15 and 17 in the second region b) of the substrate 13 of the structure illustrated in FIGS. 7A to 7D.

More specifically, FIG. 8A illustrates a sectional view along a cutting plane identical to that shown in FIG. 7C, i.e., a cut through the region a) of substrate 13 where the FinFET transistors are formed, and FIG. 8B illustrates a sectional view along a cutting plane identical to that shown in FIG. 7D, i.e., a cut through the region b) of substrate 13 where the selection bipolar transistors are formed.

By way of example, in this step, the substrate 13 is doped so as to create, in an upper part of the substrate 13, the N-type doped layer 15 and, in a lower part of the substrate 13, the P-type doped layer 17. By way of example, in this step, the implantation is performed in such a way that the junction between layer 15 and layer 17 is shallower than the trenches 14a and 14b.

By way of example, this step is performed only in the second region b) of substrate 13. At the end of this step, the first region a) of substrate 13 includes none of the layers 15 and 17.

FIGS. 9A and 9B illustrate schematic partial sectional views of a structure obtained at the end of forming sacrificial gates 67 on the surface of the structure illustrated in FIGS. 8A and 8B.

More specifically, in this step, sacrificial gates 67 are formed on the upper face of substrate 13 in the first region a) and in the second region b). The gates 67 include, for example, a so-called sacrificial material. By way of example, the gates 67 include a semiconducting layer, for example of polycrystalline silicon. By way of example, the gates 67 further include a dielectric layer, for example made of silicon nitride, on the semiconductor layer.

For example, gates 67 are formed by depositing whole wafer the above-mentioned layers prior they are etched.

FIGS. 10A and 10B illustrate schematic partial sectional views of a structure obtained at the end of a step of forming spacers 21 and 68 on the structure illustrated in FIGS. 9A and 9B.

More specifically, in this step, spacers 68 are formed on the first region a) of the substrate 13 illustrated in FIG. 9A, and spacers 21 are formed on the second region b) of the substrate 13 illustrated in FIG. 9B, forming spacers 68 being illustrated in FIG. 10A, and forming spacers 21 being illustrated in FIG. 10B.

By way of example, spacers 68 and 21 are formed in a one and the same step by depositing a layer on the upper face of the structure illustrated in FIGS. 9A and 9B. In this step, said layer covers the upper face of the substrate 13 in the first a) and second b) regions and the sides and upper face of the gates 67.

Alternatively, the spacers 68 and 21 are formed in two consecutive steps. By way of example, spacers 68 may be formed by depositing a layer on the upper face of substrate 13 while the second region b) is masked. The spacers 21 are similarly formed by depositing a layer on the upper face of the substrate 13 while the first region a) is masked.

By way of example, on the upper face of substrate 13, the layer(s) forming the spacers 68 and 21 is (are), for example, at the end of this step, removed so that they remain only in contact with the gates 67.

FIGS. 11A and 11B illustrate schematic partial sectional views of a structure obtained at the end of forming regions 70 and 29 on and in the substrate 13 of the structure illustrated in FIGS. 10A and 10B.

More specifically, in this step, regions 70 are formed in the first region a) of the substrate 13 illustrated in FIG. 10A, and regions 29 are formed in the second region b) of the substrate 13 illustrated in FIG. 10B, forming regions 70 being illustrated in FIG. 11A, and forming regions 29 being illustrated in FIG. 11B.

By way of example, regions 70 and 29 are formed by epitaxy, and then implanting N-type dopant atoms. Regions 70 and 29 have, for example, their upper faces offset from the upper face of substrate 13. By way of example, the upper face of regions 70 and 29 are forward with respect to the upper face of substrate 13, opposite the gates 67.

Regions 70 extend, for example, longitudinally between gates 67, and between gates 67 and trenches 14a. Regions 29 extend, for example, between gates 67 and trenches 14a only on one of the two sides of each gate 67.

By way of example, regions 70 and 29 are formed in one and the same step. Alternatively, regions 70 and 29 are formed in two consecutive steps.

By way of example, regions 70 correspond to the future source and drain regions of NMOS FinFET transistors. In such a structure, the drain of a transistor corresponds to the source of the adjacent transistor.

FIGS. 12A and 12B illustrate schematic partial sectional views of a structure obtained at the end of a step of forming regions 72 and 27 on and in the structure illustrated in FIGS. 11A and 11B.

More specifically, in this step, regions 72 are formed in the first region a) of the substrate 13 illustrated in FIG. 11A, and regions 27 are formed in the second region b) of the substrate 13 illustrated in FIG. 11B, forming regions 72 being illustrated in FIG. 12A, and forming regions 27 being illustrated in FIG. 12B.

By way of example, regions 72 and 27 are formed by epitaxy and then implanting P-type dopant atoms. For example, the upper faces of regions 72 and 27 are offset from the upper face of substrate 13. By way of example, the upper face of regions 72 and 27 are forward with respect to the upper face of substrate 13.

For example, regions 72 longitudinally extend between gates 67, and between gates 67 and trenches 14a. For example, regions 27 extend between gates 67 and trenches 14a only on one of the two sides of each gate 67.

By way of example, regions 72 and 27 are formed within one and the same step. Alternatively, regions 72 and 27 are formed in two consecutive steps.

By way of example, regions 72 correspond to the future source and drain regions of PMOS FinFET transistors. In such a structure, the drain of a transistor corresponds to the source of the adjacent transistor.

By way of example, at the end of the steps in FIGS. 11 and 12, in and on the first region a) of the substrate 13, areas extending between two trenches 14a have their gates 67 surrounded only by regions 70 so that NMOS or N-channel metal-oxide-semiconductor transistors are formed within. Similarly, by way of example, at the end of the steps of FIGS. 11 and 12, in and on the first region a) of the substrate 13, areas extending between two trenches 14a have their gates 67 surrounded only by regions 72 so that PMOS or P-channel metal-oxide-semiconductor transistors are formed within.

By way of example, at the end of the steps shown in FIGS. 11 and 12, the gates 67 in and on the second region b) are surrounded on one side by regions 29 and on the other by regions 27.

FIGS. 13A and 13B illustrate schematic partial sectional views of a structure obtained at the end of a step of forming a layer 74 on the upper face of the structure illustrated in FIGS. 12A and 12B, and a step of polishing the structure thus obtained.

More specifically, in this step, the layer 74 is, in a first stage, formed on the upper face of the structure illustrated in FIGS. 12A and 12B by covering the upper face of the substrate 13, in its first a) and second b) regions, the upper faces of the regions 70, 72, 27, and 29, and the gates 67.

In a second stage, the structure thus obtained undergoes CMP so as to remove an upper part of layer 74 and expose the upper face of gates 67. In this step, an upper part of the spacers 68 and 21 is further removed along with the layer 74. At the end of this step, the spacers remain only on the sides of the gates 67. At the end of this step, the upper face of the gates 67 is flush with the upper face of the layer 74.

FIGS. 14A and 14B illustrate schematic partial sectional views of a structure obtained at the end of a step of removing the sacrificial gates 67 from the structure illustrated in FIGS. 13A and 13B, and filling the openings thus formed with a layer 76.

More specifically, in this step, the material constituting the gates 67 is removed in a first stage. Openings are then created in layer 74, surrounded by spacers 68 and 21, and opening onto the upper face of substrate 13. It is considered that gates 67 are thus “emptied”.

In a second stage, a layer 76 is deposited on the upper face of the structure thus formed. By way of example, the layer 76 is deposited on the upper face of the structure so that the openings formed in place of the gates 67 are filled by the layer 76. For example, the layer 76 is made of a metal material, such as titanium nitride, tantalum nitride and/or tungsten. By way of example, layer 76 includes several sub-layers made of one or more of the above materials. By way of example, depositing layer 76 in the openings formed in place of gates 67 is preceded by a step of depositing, in these same openings, an oxide and a dielectric material having a high dielectric permittivity.

By way of example, at the end of this step, the structure undergoes a CMP step so as to expose the upper face of layer 74, so that layer 76 remains only in the openings.

At the end of this step, layer 76 corresponds to metal gates 77 in the openings of layer 74.

FIGS. 15A and 15B illustrate schematic partial sectional views of a structure obtained at the end of a step of forming trenches 16 and 78 in the structure illustrated in FIGS. 14A and 14B.

More specifically, in this step, trenches 78 are formed in and opposite the first region a) of the substrate 13 illustrated in FIG. 14A, and trenches 16 are formed in and opposite the second region b) of the substrate 13 illustrated in FIG. 14B, forming trenches 78 being illustrated in FIG. 15A, and forming trenches 16 being illustrated in FIG. 15B.

In this step, trenches 78 and 16 are formed, for example, in place of some of the metal gates 77. More precisely, the trenches 78 are formed, for example, in place of only some of the metal gates 77 in the first region a) of the substrate 13, and the trenches 16 are formed in place of all metal gates 77 in the second region b) of the substrate 13.

The trenches 78 and 16 are formed, for example, by removing the metal material contained in the gates 77. At the end of the removing step, the openings thus created are, for example, extended deep through the substrate 13, without opening onto the layer 17. At the end of this step, the extended openings are filled with a dielectric material, such as an oxide.

For example, the step of filling the openings with dielectric material is followed by a CMP step so as not to leave any of the aforementioned material on the upper face of layer 74.

By way of example, at the end of this step, trenches 16 and 78 correspond to Single Diffusion Break (SDB) structures.

For example, trenches 16 and 78 have the same depth.

Alternatively, trenches 16 and 78 have different depths.

By way of example, in the first region a) of substrate 13, trenches 78 insulate two NMOS FinFET transistors on the left-hand side of FIG. 15A from two PMOS FinFET transistors on the right-hand side of FIG. 15A.

FIGS. 16A and 16B illustrate schematic partial sectional views of a structure obtained at the end of a step of removing layer 74 from the structure illustrated in FIGS. 15A and 15B, and depositing insulating layer 18 on the structure thus formed.

In this step, the layer 74 is removed, for example, and the insulating layer 18 is deposited on the upper face of the structure. By way of example, layer 18 is deposited opposite the first a) and second b) regions of substrate 13.

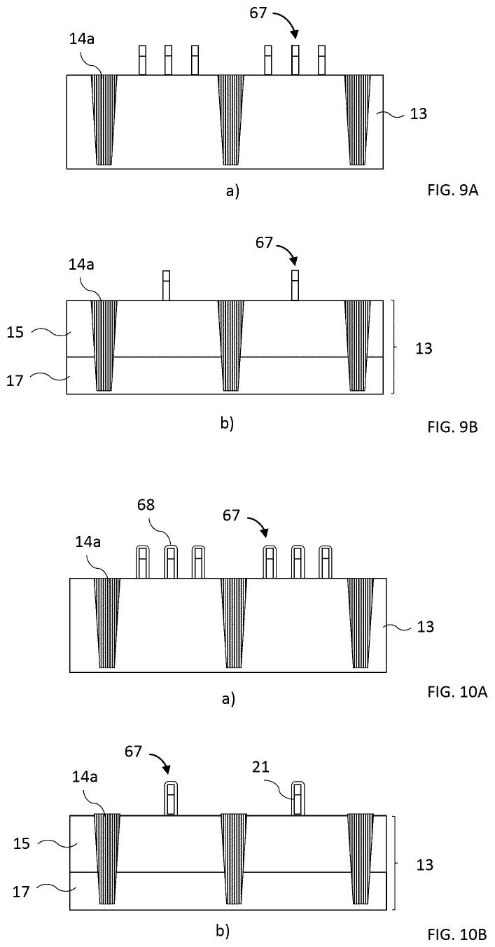

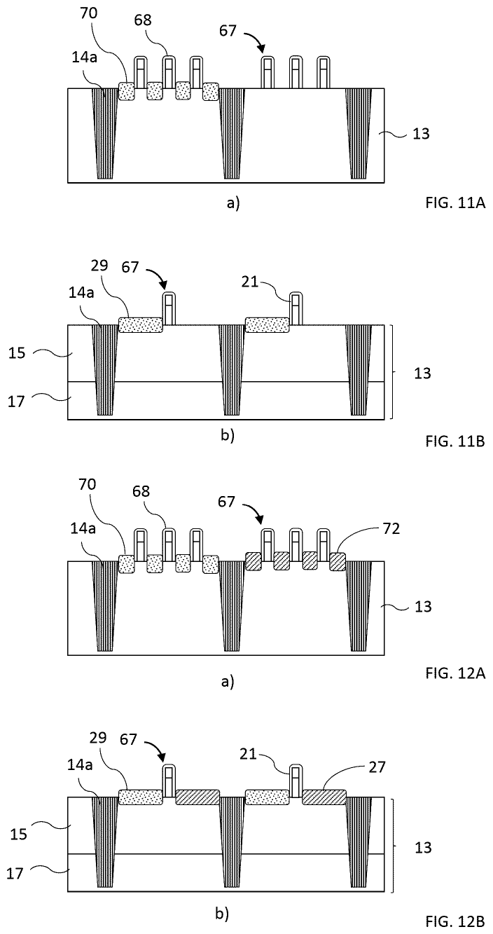

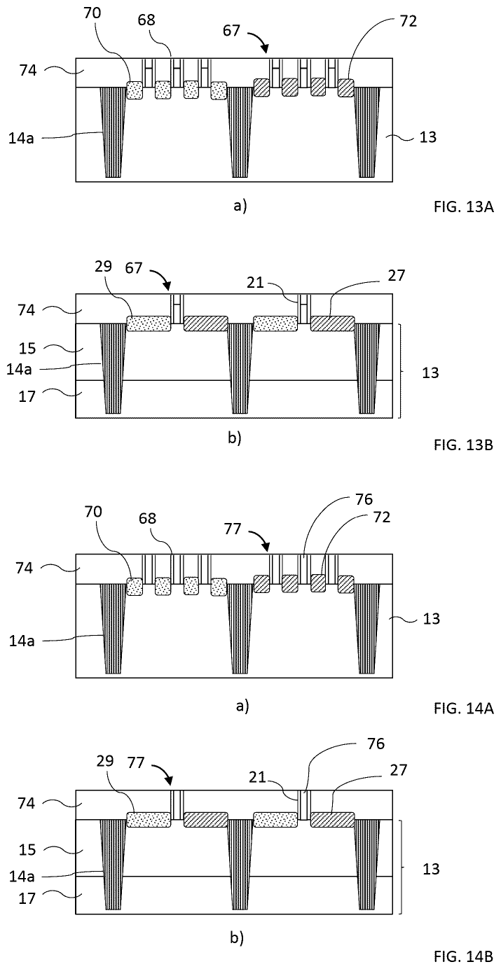

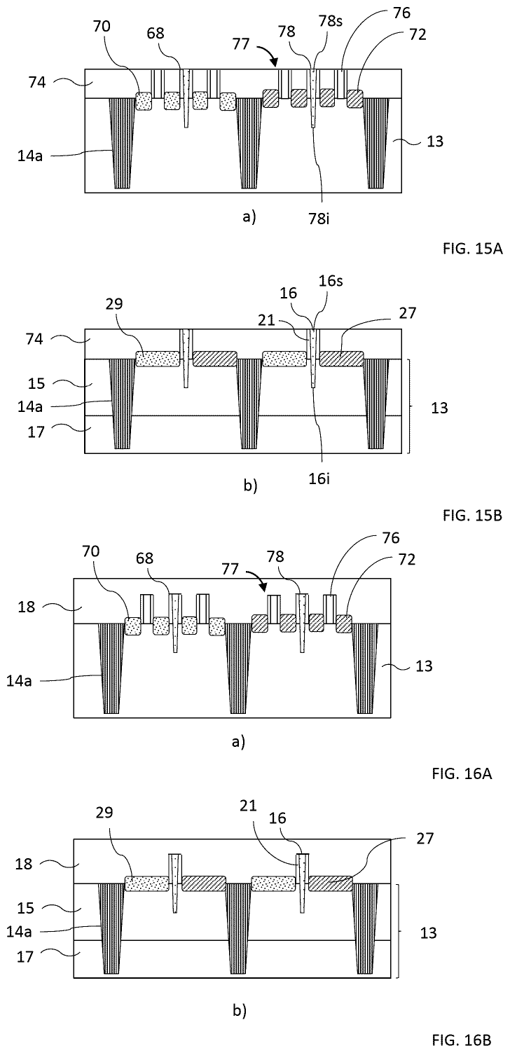

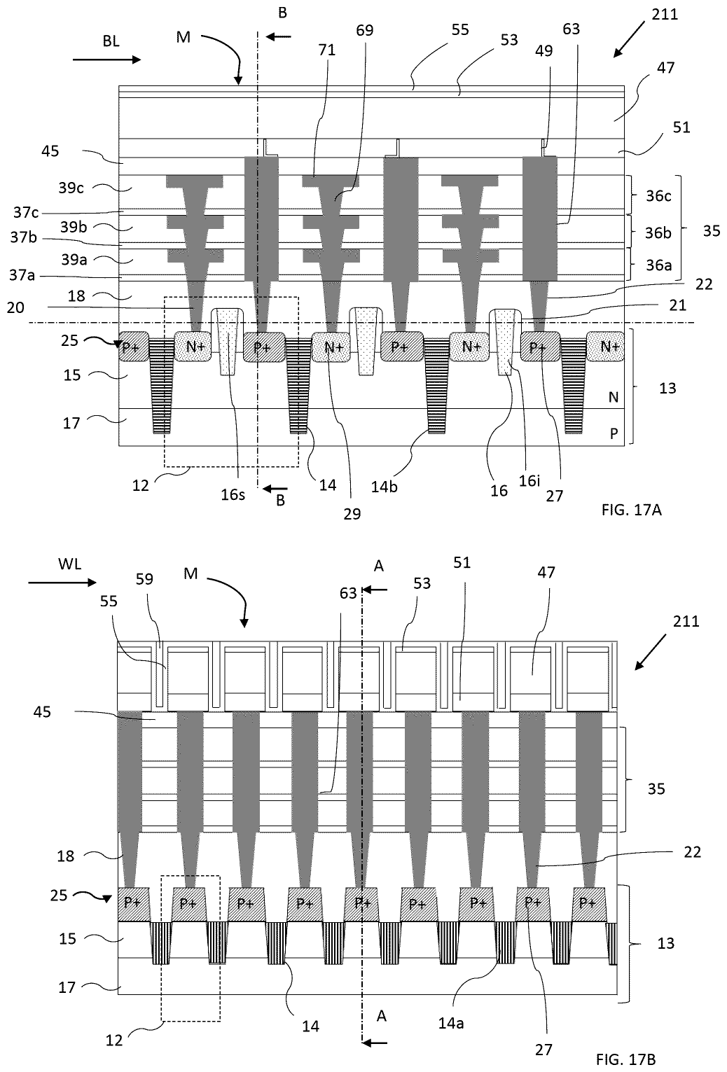

FIG. 17A and FIG. 17B are schematic partial sectional views of an example electronic device 211 according to a second embodiment, FIG. 17A being a sectional view along sectional plane AA shown in FIG. 17B, and FIG. 17B being a sectional view along sectional plane BB shown in FIG. 17A.

More particularly, FIGS. 17A and 17B are views illustrating an electronic device 211 different from the device 11 illustrated in connection to FIGS. 1A to 1C with the difference that, in the device 211, the trenches 14a are not STI trenches but are so-called FIN trenches formed similarly to the trenches 60 defining the fins of FinFET transistors.

By way of example, the trenches 14a of device 211 are thus shallower than the trenches 14a of device 11. In addition, the trenches 14a of device 211 are, for example, less wide than the trenches 14a of device 11. Further, the trenches 14a of device 211 have, for example, a repetition pitch greater than the repetition pitch of the trenches 14a of device 11. In this embodiment, the trenches define fins which have a width of between 15 nm and 50 nm, for example between 20 nm and 30 nm, for example of the order of 25 nm. In this embodiment, the memory elements M are thus closer together in device 211 than in device 11.

Device 211 has, for example, a manufacturing process compatible with the manufacturing process of device 11 described in connection to FIGS. 2 to 16B except that trenches 14b are formed similarly to trenches 60, for example before, after, or concurrently with trenches 60. The process for manufacturing device 211 further differs from the process described above in that the step described in connection with FIG. 6 is omitted. By way of example, in this embodiment, layer 15 may extend deeper than trenches 14a. This means that trenches 14a do not open onto layer 17.

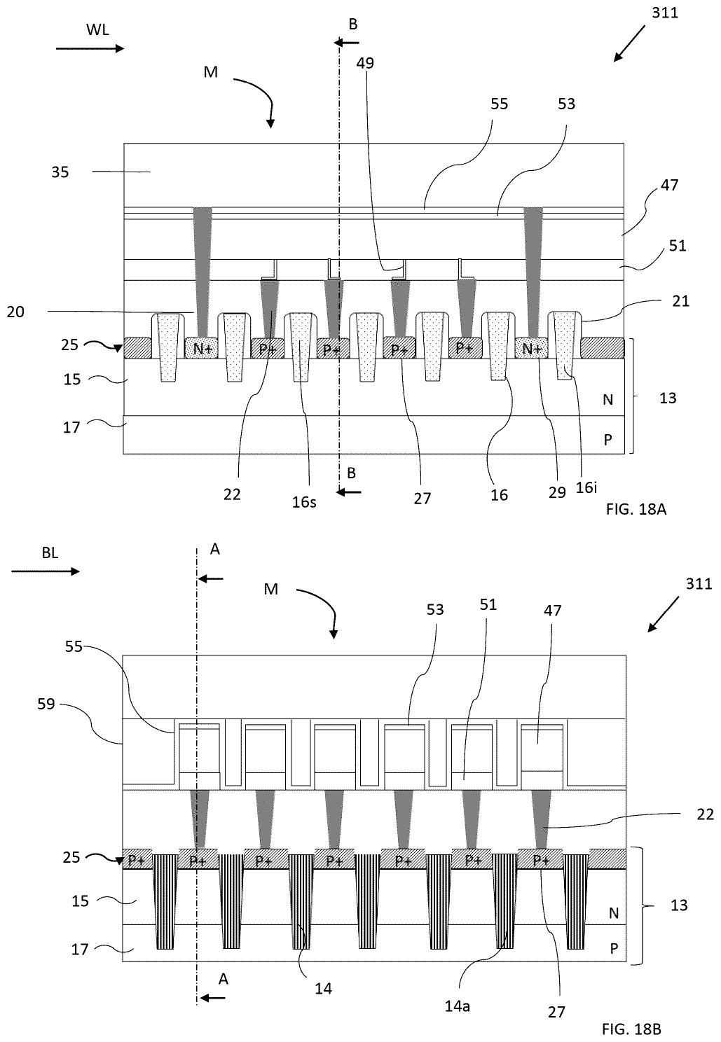

FIG. 18A and FIG. 18B are schematic partial views of an example electronic device according to a third embodiment, FIG. 18A being a sectional view along cutting plane AA shown in FIG. 18B, and FIG. 18B being a sectional view along cutting plane BB shown in FIG. 18A.

More particularly, FIGS. 18A and 18B are views illustrating an electronic device 311 different from the device 11 illustrated in connection to FIGS. 1A to 1C in that, in the device 311, there is no contact recovery by tracks 71 and vias 69 for each memory cell. In addition, in this embodiment, the layers 47 and 53 extend along the direction of the word lines, and the metal elements 49 extend along the direction of the bit lines. Further, the electronic device 311 differs from the device 11 illustrated in connection to FIGS. 1A to 1C in that the memory elements M are formed between the interconnection network 35 and the substrate 13. In this embodiment, layer 25 does not include alternating regions 27 and 29, so there are no trenches 14b.

By way of example, in this embodiment, trenches 16 are present to separate two adjacent regions 27, and to separate regions 27 from adjacent regions 29.

One advantage of the present embodiment is that it allows FinFET transistors and bipolar selection transistors to be integrated into one and the same electronic device, while being compatible with the usual process for manufacturing FinFET and bipolar selection transistor. Indeed, the present embodiment allows the trenches 16 in a bipolar selection transistor to be formed using steps present in the usual process for manufacturing FinFET transistors.

Numerous applications can benefit from the advantages of electronic device 11, electronic device 11 thus being integrable into various types of device.

By way of example, electronic device 11 may be integrated within a device intended to automotive industry. Electrifying motor vehicles causes a high increase of the number of electronics components in vehicles. The device includes for example thyristors, rectifiers, voltage transient voltage protection diodes, modules, etc., intended to be integrated within said vehicles. Furthermore, driving automation or assistance cause an increase of the number of electronics components in vehicles. The device includes for example voltage transient voltage protection diodes, an electromagnetic discharge protection, and common mode filters allowing the device to be protected against electric hazards.

By way of example, electronic device 11 may for example be used in a device intended to industry field. Particularly, the device is for example used in developing green energies, or infrastructure electrification, for example for charge stations or in integrating solar energy. The device could also be used in the fields of Internet of Things or smart home. For example, the device is intended to be implemented in circuits supplying power to equipment, for example including 800 V or 1 200 V thyristors, 1 200 V ultrafast silicon carbide diodes, transient voltage suppression diodes, and electromagnetic discharge protections. The device could also be used to implement computing systems in cloud, 5G radiofrequency communication networks, datacenters, and servers. For example, the device includes wide bandgap material.

By way of example, electronic device 11 may be integrated in a device intended to be used in personal electronics, for example in order to increase an amount of information exchanged via RF communication, in 5G communication systems, or more generally in any connected device. The device is for example a mobile phone, or a smartphone, or is part of an Internet of Things network. The device is, for example connected via 5G, WiFi, or broadband communication. For example, the device includes high rate interfaces, for example with advanced filtering and electromagnetic discharge protection.

By way of example, the electronic device 11 may be integrated in device intended to be used in communications equipment, or in computers and peripherals. For example, the device is used in 5G infrastructures and dedicated datacenters. For example, the device includes silicon carbide diodes, Schottky power transistors, electromagnetic discharge protections, and transient voltage suppression diodes. The device may also be used in satellites including for example integrated passive devices for RF applications.

Various embodiments and variants have been described. Those skilled in the art will understand that certain features of these embodiments can be combined and other variants will readily occur to those skilled in the art. In particular, the second and third embodiments illustrated in FIGS. 17A and 17B and FIGS. 18A and 18B respectively are compatible.

In addition, although embodiments have been described in which the memory elements M are formed above the interconnection stack 35, the embodiments are not limited to this specific case. Alternatively, the memory elements M may be formed between the interconnection stack 35 and the substrate 13.

Further, although an embodiment has been described in which regions 70 and 29 are formed in substrate 13 before regions 72 and 27, it may be possible to reverse the formation of these regions. Similarly, although an embodiment has been described in which the trenches 14b are formed in the substrate 13 before the trenches 14a, it may be possible to reverse the formation of these trenches.

Finally, the practical implementation of the embodiments and variants described herein is within the capabilities of those skilled in the art based on the functional description provided hereinabove.

In one embodiment, an electronic device (11; 211; 311) includes a semiconductor substrate (13); an insulating layer (18) covering the semiconductor substrate, on and in contact with the semiconductor substrate; and a memory circuit including a plurality of memory cells, each including a bipolar selection transistor (12) disposed in and on the semiconductor substrate, each bipolar selection transistor including a base region (29, 15), an emitter region (27), and a collector region (17), wherein each bipolar selection transistor includes an insulation structure (16) made of a first dielectric material, the insulation structure including an upper part (16s) extending vertically through the insulating layer (18), and a lower part (16i) extending vertically through the semiconductor substrate (13) between the base region (29) and the emitter region (27), the side faces of the upper part (16s) of the insulation structure (16) being covered by spacers (21) made of a second dielectric material.

In one embodiment, the device, further includes a logic circuit including a plurality of fin field-effect transistors disposed in and on the semiconductor substrate, each fin field-effect transistor including a source region (70, 72) and a drain region (70, 72), wherein two adjacent fin field-effect transistors are separated by a further insulation structure (78) made of the first dielectric material, the insulation structure including an upper part (78s) extending vertically through the insulating layer, and a lower part (78i) extending vertically through the semiconductor substrate between the drain region and the source region of the two adjacent transistors, the side faces of the upper part (78s) of the insulation structure being covered by spacers (68) of the second dielectric material.

In one embodiment, the insulation structures (16) of the memory circuit and the insulation structures (78) of the logic circuit have the same depth.

In one embodiment, the insulation structures (16) of the memory circuit and the insulation structures (78) of the logic circuit have different depths.

In one embodiment, each memory cell includes a memory element (M) including a layer (47) made of a phase-change material.

In one embodiment, the memory circuit includes an interconnection stack (35) arranged on the semiconductor substrate (13), including a succession of levels (36) in which interconnection elements (63, 69, 71) are defined.

In one embodiment, the memory elements (M) are arranged above the interconnection stack (35).

In one embodiment, a process for manufacturing, in and on a semiconductor substrate (13), an electronic device including a memory circuit including a plurality of memory cells each including a selection bipolar transistor (12) formed in and on the semiconductor substrate, each selection bipolar transistor including a base region (29, 15), an emitter region (27), and a collector region (17), the process including the steps of: forming sacrificial gates (67) made of sacrificial material on the semiconductor substrate (13); forming spacers (21) made of dielectric material on the side faces of the sacrificial gates; removing the sacrificial material in the sacrificial gates, and etching the substrate opposite the sacrificial gates so as to form openings surrounded in an upper part by the spacers and extending in a lower part through the substrate, and filling the openings with another dielectric material so as to form insulation structures (16) made of the other dielectric material; and forming an insulating layer (18) on and in contact with the semiconductor substrate (13), the insulation structures thus including an upper part (16s) extending vertically through the insulating layer (18), and a lower part (16i) extending vertically through the semiconductor substrate (13) between the base region (29) and the emitter region (27) of the bipolar transistors, the side faces of the upper part (16s) of each insulation structure (16) being covered by the spacers (21).

In one embodiment, the device further includes a logic circuit, the logic circuit including a plurality of fin field-effect transistors each including a source region (70, 72) and a drain region (70, 72), the process including the steps of: forming sacrificial gates (67) made of a sacrificial material on the semiconductor substrate (13); forming spacers (68) made of the dielectric material on the side faces of the sacrificial gates; removing the sacrificial material in the sacrificial gates, and etching the substrate opposite the sacrificial gates so as to form openings surrounded in an upper part by the spacers and extending in a lower part through the substrate, and filling the openings with the other dielectric material so as to form further insulation structures (78) made of the other dielectric material; and forming the insulating layer (18) on and in contact with the semiconductor substrate (13), the further insulation structures thus including an upper part (78s) extending vertically through the insulating layer (18) and a lower part (78i) extending vertically through the semiconductor substrate (13) between the source region (70, 72) and the drain region of each fin field-effect transistor, the side faces of the upper part (78s) of the further insulation structure (78) being covered by the spacers (68).

In one embodiment, steps of forming the insulation structures (16) of the memory circuit and the further insulation structures (78) of the logic circuit are common.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a semiconductor substrate;
an insulating layer covering the semiconductor substrate, on and in contact with the semiconductor substrate; and
a memory circuit including a plurality of memory cells, each including a bipolar selection transistor disposed in and on the semiconductor substrate, each bipolar selection transistor including a base region, an emitter region, and a collector region,
wherein each bipolar selection transistor includes an insulation structure made of a first dielectric material, the insulation structure including an upper part extending vertically through the insulating layer, and a lower part extending vertically through the semiconductor substrate between the base region and the emitter region, side faces of the upper part of the insulation structure being covered by first spacers of a second dielectric material.

2. The device according to claim 1, further comprising a logic circuit including a plurality of fin field-effect transistors disposed in and on the semiconductor substrate, each fin field-effect transistor including a source region and a drain region,
wherein two adjacent fin field-effect transistors are separated by a second insulation structure of the first dielectric material, the second insulation structure including an upper part extending vertically through the insulating layer, and a lower part extending vertically through the semiconductor substrate between the drain region and the source region of the two adjacent fin field effect transistors, side faces of the upper part of the insulation structure being covered by second spacers of the second dielectric material.

3. The device according to claim 2, wherein the first insulation structures of the memory circuit and the second insulation structures of the logic circuit have a same depth.

4. The device according to claim 2, wherein the first insulation structures of the memory circuit and the second insulation structures of the logic circuit have different depths.

5. The device according to claim 1, wherein each memory cell includes a memory element including a layer made of a phase-change material.

6. The device according to claim 1, wherein the memory circuit includes an interconnection stack arranged on the semiconductor substrate, including a succession of levels in which interconnection elements are defined.

7. The device according to claim 6, wherein each memory cell includes a memory element including a layer made of a phase-change material wherein the memory elements are arranged above the interconnection stack.

8. A process, comprising:
forming first sacrificial gates of a first sacrificial material on a semiconductor substrate;
forming first spacers of a first dielectric material on side faces of the first sacrificial gates;
forming, in and on the semiconductor substrate, a plurality of bipolar transistors each including a base region, an emitter region, and a collector region;
forming first openings surrounded in an upper part by the first spacers and extending in a lower part through the substrate by removing the first sacrificial gates and etching the substrate;
forming first insulation structures by filling the openings with a second dielectric material; and
forming an insulating layer on and in contact with the semiconductor substrate, the first insulation structures including an upper part extending vertically through the insulating layer, and a lower part extending vertically through the semiconductor substrate between the base region and the emitter region of the bipolar transistors, side faces of the upper part of each first insulation structure being covered by the first spacers.

9. The process according to claim 8, wherein each bipolar transistor is part of a respective memory cell of a memory circuit.

10. The process according to claim 9, further comprising:
forming second sacrificial gates on the semiconductor substrate;
forming second spacers of the first dielectric material on side faces of the second sacrificial gates;
forming a plurality of fin field-effect transistors each including a source region and a drain region;
forming second openings surrounded in an upper part by the spacers and extending in a lower part through the substrate by removing the second sacrificial gates from between the second spacers and etching the substrate;
forming second insulation structures by filling the second openings with the second dielectric material, the second insulation structures including an upper part extending vertically through the insulating layer and a lower part extending vertically through the semiconductor substrate between the source region and the drain region of each fin field-effect transistor, side faces of the upper part of the second insulation structure being covered by the second spacers.

11. The process according to claim 10, wherein the fin field-effect transistors are part of a logic circuit.

12. The process according to claim 11, further comprising forming the first insulation structures and the second insulation structures simultaneously.

13. A method, comprising:
forming a first sacrificial gate structure on a semiconductor substrate;
forming first spacers of a first dielectric material on sidewalls of the first sacrificial gate structure;
forming a base region and an emitter region of a bipolar transistor in the semiconductor substrate each in contact with a respective one of the first spacers; and
replacing the first sacrificial gate structure with a first insulation structure of a second dielectric material extending into the semiconductor substate.

14. The method of claim 13, further comprising forming an insulating layer in contact with the semiconductor substrate, wherein the first insulation structure extends vertically through the insulating layer.

15. The method of claim 13, further comprising forming the base region and the emitter region in separate epitaxial growth processes from the semiconductor substrate.

16. The method of claim 12, further comprising:
forming a second sacrificial gate structure on the semiconductor substrate;
forming second spacers of the first dielectric material on sidewalls of the second sacrificial gate structure;
forming a first source/drain region of a first fin field-effect transistor and a second source/drain region of a second fin field-effect transistor each in contact with a respective one of the second spacers; and
replacing the second sacrificial gate structure with a second insulation structure of the second dielectric material extending into the semiconductor substate.

17. The method of claim 16, further comprising forming the first source/drain region, the second source/drain region, and the base region in a same first epitaxial growth process.

18. The method of claim 17, further comprising forming the emitter region in a second epitaxial growth process.

19. The method of claim 16, wherein the first and second fin field-effect transistors are part of a logic circuit.

20. The method of claim 13, wherein the bipolar transistor is part of a memory cell of a memory circuit.
